(19) United States
(12) Patent Application Publication
(10) Pub. No.: US 2011/0133314 A1
(43) Pub. Date: Jun. 9, 2011

(54) METHOD FOR PRODUCING A SEMICONDUCTOR WAFER

(75) Inventors: Georg Pietsch, Burghausen (DE); Walter Haeckl, Zeilarn (DE); Juergen Schwandner, Garching (DE); Noemi Banos, Burghausen (DE)

(73) Assignee: SILTRONIC AG, Munich (DE)

(21) Appl. No.: 12/939,324

(22) Filed: Nov. 4, 2010

(30) Foreign Application Priority Data
Dec. 9, 2009 (DE) 10 2009 057 593.6

(51) Int. Cl. H01L 29/30; H01L 21/20

(52) U.S. Cl. 257/655; 438/478; 257/E21.09; 257/E29.106

(57) ABSTRACT

A method for producing a semiconductor wafer includes pulling a single crystal of semiconductor material, slicing a semiconductor wafer from the single crystal and polishing the semiconductor wafer with the polishing pad and polishing agent. The polishing agent is free of solid materials having abrasive action and the polishing pad contains fixedly bonded solid materials with abrasive action. During polishing the polishing agent is supplied in a gap between the semiconductor wafer and polishing pad. The polishing agent has a pH value in a range of 9.5 to 12.5.

### CROSS REFERENCE TO RELATED APPLICATIONS

This application claims priority to German Patent Application No. DE 10 2009 057 593.6, filed on Dec. 9, 2009 which is hereby incorporated by reference herein in its entirety.

### FIELD

The present invention relates to a method for producing a semiconductor wafer, and particularly a method including pulling a single crystal, slicing the crystal into wafers and polishing the semiconductor wafers.

### BACKGROUND

Semiconductor wafers with extreme requirements for global and local flatness, single-side-referenced local flatness (nanotopology), roughness and cleanness are required for electronics, microelectronics and microelectromechanics. Semiconductor wafers are wafers composed of semiconductor materials, in particular compound semiconductors such as gallium arsenide and predominantly elemental semiconductors such as silicon and occasionally germanium. Semiconductor wafers are produced in a multiplicity of successive process steps, which can generally be classified into the following groups:

a) producing a monocrystalline semiconductor rod (crystal growth);

b) slicing the rod into individual wafers;

c) mechanical processing;

d) chemical processing;

e) chemomechanical processing;

f) if appropriate producing layer structures.

Crystal growth is effected by pulling and rotating a pre-oriented monocrystalline seed from a silicon melt (crucible pulling method, Czochralski method) or by recrystallizing a polycrystalline crystal deposited from the vapor phase along a melting zone which is produced by means of an induction coil and is led slowly axially through the crystal (zone melting method). The crucible pulling method is of particular importance in terms of the frequency of use and for the present invention. It is described in greater detail below.

In the crucible pulling method, high-purity polycrystalline silicon obtained by means of vapor phase deposition from trichlorosilane is melted with addition of dopant in a quartz glass crucible under a protective gas atmosphere. A seed crystal obtained beforehand from a monocrystalline silicon rod, said seed crystal having been oriented in the desired crystallographic direction of growth by means of X-ray diffraction, is dipped into the melt and pulled from the melt slowly with rotation of the single crystal, often also additionally with rotation of the melting crucible. The heat of fusion is produced by resistive and if appropriate additionally inductive heating. Various methods for temperature regulation, insulation and shielding of the resulting single crystal rod, which undesirably dissipates heat from the melt, are used in order to ensure low-stress crystal growth from the melt via the solid/liquid phase boundary layer up to the further cooled start of the rod and thus to avoid the formation of stress-induced crystal damage (crystalline dislocations). Magnetic fields can also be used which permeate the melt and so further influence convection and mass transport phenomena.

Examples of crucible pulling methods are described in DE 100 25 870 A1, DE 102 50 822 A1, DE 102 50 822 A1 or DE 101 18 482 B4.

One form of the growth interface that is characteristic of the respective process parameters is formed in the complex interplay of melting convection and diffusion, dopant segregation at the growth interface and thermal conduction and radiation of melt and rod. In this case, convection is understood to mean the material movement driven by density fluctuations on account of non-uniform heating; diffusion is understood to mean the (short-range) movement of the atoms in the melt, said movement being driven by concentration gradients; and segregation is understood to mean the accumulation of dopant in rod or melt on account of different solubilities in the semiconductor material in the liquid or solid phase. By changing the operating parameters of the crystal pulling installation (pulling rate, temperature distribution, etc.), it is possible to vary the form of the growth interface, that is to say the interface between liquid and solid phases of the semiconductor material, in wide limits.

FIG. 1 shows single crystal and melt composed of semiconductor material in the pulling crucible with a substantially flat 5, concave 5a and convex 5b phase interface.

Furthermore, the complex material transport phenomena in the melt and during the material deposition at the phase interface lead to a spatially fluctuating concentration of the deposited dopant in the growing semiconductor single crystal. On account of the rotational symmetry of the pulling process, pulling apparatus and growing semiconductor rod, the dopant concentration fluctuations are substantially radially symmetrical, that is to say that they form concentric rings of fluctuating dopant concentration along the axis of symmetry of the semiconductor single crystal. These dopant concentration fluctuations are also referred to as “striations”.

FIG. 2a shows single crystal and melt composed of semiconductor material with a substantially flat liquid/solid phase interface 5 with radially fluctuating dopant concentrations 6. After the semiconductor crystal has been sliced along the cutting surface, these “striations” cover the obtained semiconductor wafers 9 as concentric rings (FIG. 2b). The latter can be made visible by measurement of the local surface conductivity or structurally as unevenness after treatment with a defect etch. Further, it has been shown that the spatial frequency of the dopant concentration fluctuations is dependent on the flatness of the solid/liquid interface during crystal growth. In the case of curved interfaces, striations form in the region where the interface has a large gradient, in spatially particularly short-wave (spatially high-frequency) succession. The concentration fluctuation rings lie close together. In the region where the growth interface is substantially flat, by contrast, the dopant concentration fluctuates only very slowly. The fluctuation rings are far apart from one another and the amplitude of the concentration fluctuation is small.

Sawing the semiconductor rod in order to slice it into individual semiconductor wafers leads to near-surface layers (13) of the resulting semiconductor wafers whose monocrystallinity is damaged (FIG. 2c). These damaged layers are subsequently removed by chemical and chemomechanical processing. An example of chemical processing is alkaline or acidic etching; an example of chemomechanical processing is polishing using an alkaline colloidally disperse silica sol.

Further, the material removal rate in chemical or chemomechanical processing of the surface of a semiconductor wafer is dependent on the local chemical or electronic properties of the semiconductor surface. This results from the fact that different concentrations of incorporated dopant atoms modify the semiconductor host lattice electronically (local valence, conductivity) or, on account of size mismatch, structurally by means of distortion and, in the case of chemical or chemomechanical processing, this leads to a preferential material removal dependent on the dopant concentration. Ring-shaped unevennesses are formed in the surface of the semiconductor wafer, in accordance with the dopant concentration fluctuations. This concentric height modulation of the surface after chemical or chemomechanical processing is likewise referred to as “striations”.

DE 102 007 035 266 A1 describes a method for polishing a substrate composed of semiconductor material, comprising two polishing steps of the FAP type, which differ in that a polishing agent slurry containing non-bonded abrasive material as solid material is introduced between the substrate and the polishing pad in one polishing step, while the polishing agent slurry is replaced by a polishing agent solution free of solid materials in the second polishing step.

Semiconductor wafers suitable as a substrate for particularly demanding applications in electronics, microelectronics or microelectromechanics generally have a particularly high degree of flatness and homogeneity of their surface. This is because the flatness of the substrate wafer crucially limits the achievable flatnesses of the individual circuit planes of typical multilayer components which are subsequently patterned photolithographically thereon. If the initial flatness is insufficient, breakthroughs through the applied insulation layers will occur later during the various processes of planarizing the individual wiring planes, thus leading to short circuits and hence failure of the components thus produced.

Therefore, semiconductor wafers having as far as possible weak and long-wave dopant concentration fluctuations 7 (FIG. 2b) are conventionally preferred. These can be achieved in the prior art only by means of crystal pulling processes in which the growth surface 5 is as flat as possible (FIG. 2a).

Such pulling processes are particularly slow, complicated to control and therefore very uneconomic.

Conventional crystal pulling processes and subsequent chemical and chemomechanical processing processes make it possible to produce only semiconductor wafers which are limited in terms of the achievable flatness and which are unsuitable for future applications making particularly high requirements on the flatness. Moreover, these production methods are very expensive and complicated since, during crystal growth, it is necessary to maintain a particularly flat growth interface at which the semiconductor material grows only very slowly from the melt to form a single crystal.

### SUMMARY

An aspect of the present invention is to provide a method by which a single crystal can be produced cost-effectively, by means of a crystal pulling process that can be handled in a simple manner, and with high yield and can be processed by means of suitable surface processing to form a semiconductor wafer having few defects which has a particularly high final flatness which is not limited by dopant concentration fluctuations.

In an embodiment, the present invention provides a method for producing a semiconductor wafer, comprising pulling a single crystal composed of semiconductor material, slicing a semiconductor wafer from the single crystal and polishing the semiconductor wafer, wherein a polishing pad used in this case contains fixedly bonded solid materials with abrasive action and a polishing agent which contains no solid materials with abrasive action and which has a pH value of between 9.5 and 12.5 is supplied to a working gap formed between a surface of the semiconductor wafer that is to be polished and the polishing pad.

In another embodiment, the present invention provides a method for producing a semiconductor wafer, comprising pulling a single crystal (3) composed of semiconductor material from a melt (2), slicing a semiconductor wafer (9) from the single crystal (3) and polishing the semiconductor wafer (9), wherein the polishing is effected using a polishing pad containing fixedly bonded solid materials with abrasive action, wherein a polishing agent supplied during the polishing contains no solid materials with abrasive action and has a pH value of between 9.5 and 12.5, and wherein, during the crystal growth, an edge region of the single crystal (3) is produced with great and spatially high-frequency fluctuation of the dopant concentration and a center region is produced with low and spatially low-frequency fluctuation of the dopant concentration.

### BRIEF DESCRIPTION OF THE DRAWINGS

Exemplary embodiments of the invention are described in greater detail below, making reference to the drawings, in which:

FIG. 1 shows a crystal and melt composed of semiconductor material in the pulling crucible with substantially flat, concave or convex solid/liquid phase interface;

FIG. 2a shows a crystal and melt composed of semiconductor material in the pulling crucible with flat solid/liquid phase interface and uniform distribution of the dopant concentration fluctuations;

FIG. 2b shows a plan view of a semiconductor wafer (cut through the single crystal in FIG. 2a);

FIG. 2c shows a section through a semiconductor wafer with damaged surface zone;

FIG. 2d shows a section through a semiconductor wafer after removal of the damaged surface zone with resulting great unevenness of the surface;

FIG. 2e shows a section through a semiconductor wafer after in accordance with an embodiment of the invention;

FIG. 3a shows a crystal and melt composed of semiconductor material in the pulling crucible with approximately trapezoidal concave solid/liquid phase interface;

FIG. 3b shows a plan view of a semiconductor wafer (cut through the single crystal in FIG. 3a;

FIG. 3c shows a section through a semiconductor wafer after slicing from the single crystal with a damaged surface zone;

FIG. 3d shows a section through a semiconductor wafer after slicing from the single crystal and subsequent removal of the damaged surface zone by chemomechanical polishing method with resulting great unevenness of the surface;

FIG. 3e shows a section through a semiconductor wafer after slicing from the single crystal in accordance with an embodiment of the invention.

### LIST OF REFERENCE SYMBOLS USED

1 pulling crucible (quartz crucible);
   2 melt (liquid phase);
   3 single crystal (solid Phase);
   4 surface of the silicon melt (liquid/gas interface);
   5 substantially flat liquid-solid interface (growth surface);
   5a concave growth surface with substantially constant curvature;
   5b convex growth surface with substantially constant curvature;
   6 region of increased dopant concentration;
   7 spatial frequency of the dopant concentration fluctuations;
   7a region of long-wave fluctuation of the dopant concentration;
   7b region of short-wave fluctuation of the dopant concentration;
   8 cutting surface through single crystal;
   9 semiconductor wafer;
   10 unevenness as a result of dopant-concentration-dependant material removal;
   11 slightly reduced unevenness as a result of dopant-concentration-dependent material removal;
   12 greatly reduced unevenness as a result of dopant-concentration-dependent material removal;
   13 surface layer of the semiconductor wafer damaged in crystalline fashion.
   14 trapezoidally concavely shaped growth surface.

### DETAILED DESCRIPTION

Methods of FAP polishing (polishing of the semiconductor wafers by means of a polishing pad containing fixedly bonded solid materials with abrasive action) that correspond to the invention are described in the German applications—not previously published—having the file references 10 2008 053 610.5, 10 2009 025 243.6, 10 2009 030 297.2 and 10 2009 030 292.1, which are incorporated by reference herein in their entirety.

The invention does not require any conventional chemomechanical polishing such as DSP or CMP. The DSP is replaced by FAP polishing.

Particularly, the invention does not require polishing agents containing solid materials with abrasive action supplied during the polishing process.

The invention makes use exclusively of polishing agent solutions that are free of solid materials. As a result, the method also differs distinctly from the method described in DE 10 2007 035 266 A1 which declares that an FAP step with supply of a polishing agent slurry is essential in the two-part FAP polishing claimed therein. The object of the invention could not be achieved by this means, nor with application of chemomechanical DSP.

The pH value of the polishing agent solution is preferably set by addition of potassium hydroxide solution (KOH) or potassium carbonate (K₂CO₃).

The invention is described thoroughly below with reference to the figures.

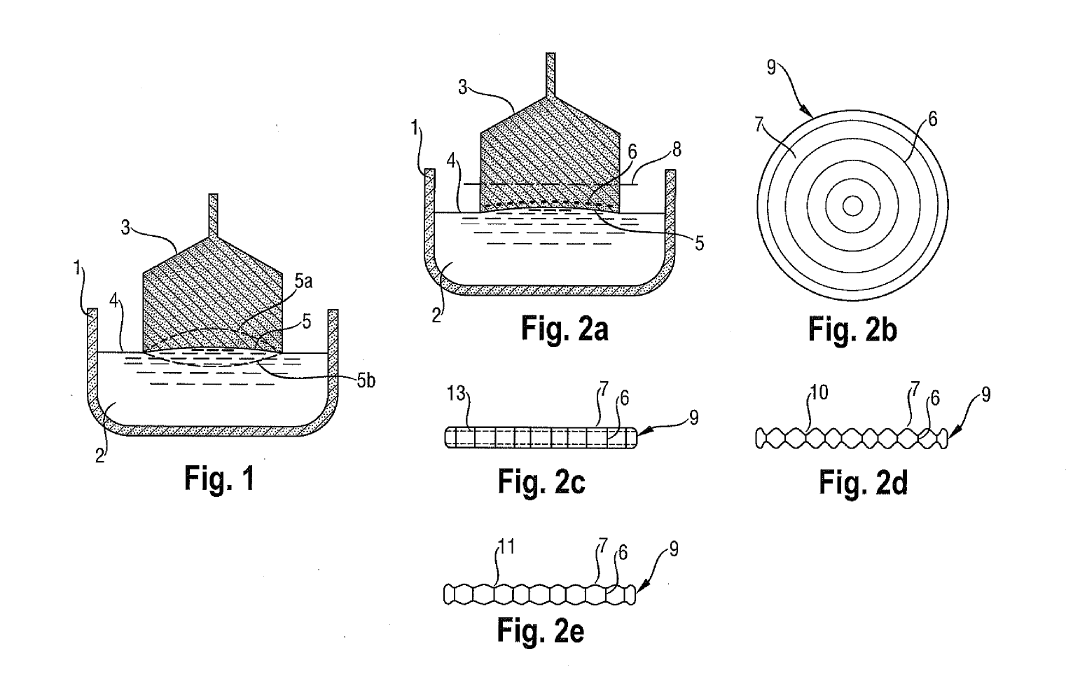

FIG. 1 shows the main elements of a single-crystal rod pulling installation, comprising melting crucible 1, melt 2 composed of semiconductor material (liquid phase), pulled single crystal 3 composed of semiconductor material (solid phase), surface 4 of the melt and various liquid-solid interfaces, that is to say growth surfaces at which the crystal growth takes place by deposition from the melt: one substantially flat 5, one concave 5a and one convex 5b.

FIG. 2a shows a comparative example of a conventional method, in which a flattest possible growth surface is preferred since, at the latter, the concentration 6 of the dopant incorporated in the crystal lattice is subject to the smallest variations and the variations take place in a spatially long-wave fashion. Individual semiconductor wafers 9 are obtained by slicing the rod 3 e.g. along the cutting plane 8 shown.

Such a semiconductor wafer 9 is shown in plan view in FIG. 2b.

The semiconductor wafers 9 which are shown in the comparative example and are obtained from a single crystal pulled according a comparative method and have a uniform spacing 7 of the dopant fluctuations. Such a crystal pulling process is very time-consuming, unproductive and expensive. By way of example, the duration for pulling a 300 mm silicon single crystal from a weighed-in quantity for melting of 250 kg is approximately 58 hours.

FIG. 2c shows the semiconductor wafers 9 obtained after slicing the rod, in side view. The crystal layers 13 near the surface are damaged by the material-processing action of the separating process. During the removal of the damaged layers and further leveling of the surface by mechanical (grinding, lapping), and chemical processing (etching), but in particular during the final polishing according to the comparative method of alkaline colloidally disperse silica sol, the dopant concentration fluctuations produce great unevennesses 10 of the semiconductor surface as a result of preferential material removal (FIG. 2d).

The semiconductor wafer which is shown in the comparative example and is obtained by means of crystal growth and silica sol polishing according to the comparative method is unsuitable as a substrate for particularly demanding applications appertaining to electronics, microelectronics or microelectromechanics, on account of the great unevenness.

FIG. 2e shows the cross section of a semiconductor wafer from a pulling method according to the comparative example but after final polishing by means of a “fixed abrasive polishing” method (FAP) in accordance with the a method according to an embodiment of the invention. During the FAP, one or a plurality of semiconductor wafers are processed in material-removing fashion simultaneously or successively, on one side, or sequentially or simultaneously on both sides, by moving the semiconductor wafer under pressure over a polishing pad. In this case, solid materials with abrasive action are fixedly bonded into the FAP polishing pad, and the polishing agent supplied to the working gap formed between polishing pad and surface of the semiconductor wafer during processing contains no solid materials with abrasive action and has a pH value of between 9.5 and 12.5.

Suitable abrasive materials for the FAP polishing pads used comprise for example particles of oxides of the elements cerium, aluminum, silicon, zirconium and particles of hard materials such as silicon carbide, boron nitride and diamond.

Particularly suitable polishing pads have a surface topography characterized by replicated microstructures. Said microstructures (“posts”) have for example the form of columns having a cylindrical or polygonal cross section or the form of pyramids or truncated pyramids.

More detailed descriptions of such polishing pads are contained for example in WO 92/13680 A1 and US 2005/227590 A1.

The use of cerium oxide particles bonded in the polishing pad is particularly preferred, also cf. U.S. Pat. No. 6,602,117 B1.

The average particle size of the abrasives contained in the FAP polishing pad is preferably 0.1-1.0 μm, particularly preferably 0.1-0.6 μm, and especially preferably 0.1-0.25 μm.

FIG. 2e shows that the unevennesses of the semiconductor surface obtained are significantly reduced 11 by such processing according to the invention in comparison with the prior art.

A semiconductor wafer processed in this way according to the a method according to this embodiment of the invention is more suitable as a substrate for more demanding applications in electronics, microelectronics or microelectromechanics than semiconductor wafers processed comparatively according to the prior art.

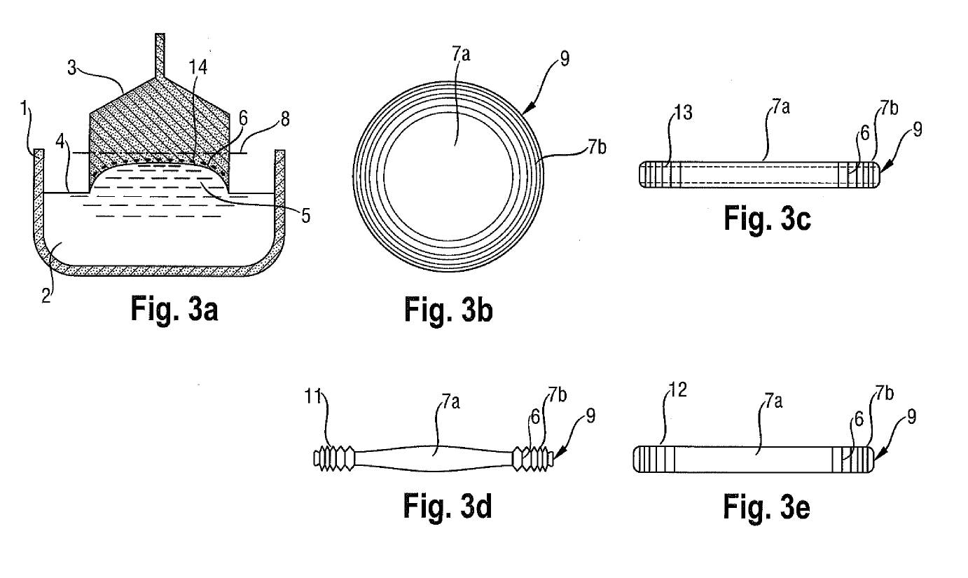

FIG. 3 elucidates the invention in accordance with a method of another embodiment.

FIG. 3a schematically shows a semiconductor single crystal 3 that was obtained by means of a particularly fast pulling method. In the present example according to the invention, the time for pulling a 300 mm crystal from a weighed-in quantity for melting of 250 kg was only 42 hours by comparison with 58 hours for a crystal pulled according to the comparative with the same weighed-in quantity with a flat liquid-solid growth interface.

The growth interface 14 in FIG. 3a is particularly greatly curved and has an approximately trapezoidal profile.

FIG. 3b shows the plan view of a semiconductor wafer 9 obtained by slicing along the cutting surface 8 in FIG. 3a. On account of the large gradient of the growth interface in the edge region of the crystal, the fluctuation of the radial concentration of the dopant incorporated at the growth interface in the edge region of the crystal is particularly high and changes at spatially high frequency 7b (small radial spacings of the concentration maxima). Within the rod 3 (FIG. 3a), the growth interface has a substantially flat profile, and so the center region of the semiconductor wafer 9 (FIG. 3b) has only a small fluctuation amplitude and very wide spacings 7a of the maxima of the dopant concentration.

FIG. 3c shows the cross section through the semiconductor wafer 9 with the near-surface zones 13 damaged by the slicing of the single crystal rod into individual semiconductor wafers.

FIG. 3d shows, as a comparative example, the processing—not according to the invention—by means of chemomechanical polishing (DSP) using alkaline colloidally disperse silica sol in accordance with a comparative method.

The preferential material removal of the edge region—which is dopant-concentration-modulated at spatially high frequency—of the semiconductor wafer leads to great spatially short-wave unevennesses 11 in the edge region 7b of the surface of the semiconductor wafer 9 and to low-frequency unevennesses in the center region 7a.

FIG. 3e shows the cross section of a semiconductor wafer after processing by this embodiment of the invention by means of final fixed abrasive polishing (FAP).

The polishing pad used during the FAP is significantly stiffer than a conventional polishing pad for silica sol polishing. As a result and owing to the fact that the abrasive is fixedly bonded into the FAP pad and is not contained in a liquid film between semiconductor wafer surface and polishing pad with a substantially indeterminate interaction, the material removal during the FAP takes place substantially in path-determined fashion, that is to say deterministically along the path of the fixedly bonded abrasives over the semiconductor wafer surface, said path being predetermined by pressure, polishing pad geometry and semiconductor wafer geometry and process kinematics.

The method according to the invention thus replaces the preferential material removal of the chemomechanical polishingby deterministic, path-determined workpiece processing. Particularly in the case of spatially short-wave modulations of the electronic, chemical or structural properties of the semiconductor wafer such as arise e.g. as a result of the dopant fluctuations owing to the formation of the “striations” during crystal growth, the stiff FA polishing according to the invention which removes material deterministically in path-determined fashion does not follow the unevennesses of the workpiece surface, but rather levels the latter. In the center region, in which the modulation amplitude is smaller and the spacings between the dopant maxima are large, the deterministically path-determined FA polishing therefore likewise leads to a particularly flat surface.

The single crystals described in the invention are preferably silicon single crystals. The semiconductor wafers are preferably monocrystalline silicon wafers.

What is claimed is:

1. A method for producing a semiconductor wafer comprising:
pulling a single crystal including semiconductor material;
slicing a semiconductor wafer from the single crystal;
supplying a polishing agent that is free of solid materials having abrasive action in a gap between the semiconductor wafer and a polishing pad containing fixedly bonded solid materials with abrasive action, the polishing agent having a pH value in a range of 9.5 to 12.5; and
polishing the semiconductor wafer with the polishing pad and polishing agent.

2. The method as recited in claim 1, wherein a solid phase and a liquid phase are present during the pulling of the single crystal, and wherein an interface between the solid phase and liquid phase, at which crystal growth occurs by deposition from the liquid phase melt, has one of a substantially flat form, a concave form and a convex form.

3. The method as recited in claim 1, wherein the solid materials having abrasive action are selected from the group consisting of cerium oxides, aluminum oxides, silicon oxides, zirconium oxides, silicon carbide, boron nitride and diamond.

4. The method as recited in claim 3, wherein the solid materials having abrasive action have a size in a range of 0.1-1.0 μm.

5. A method for producing a semiconductor wafer comprising:
pulling a single crystal including semiconductor material, so as to form a single crystal having an edge region having high fluctuation of dopant concentration at spatially high-frequency and a center region having low fluctuation of dopant concentration at spatially low-frequency;
slicing a semiconductor wafer from the single crystal;
supplying a polishing agent that is free of solid materials having abrasive action in a gap between the semiconductor wafer and a polishing pad containing fixedly bonded solid materials with abrasive action, the polishing agent having a pH value in a range of 9.5 to 12.5; and
polishing the semiconductor wafer with the polishing pad and polishing agent.

6. The method as recited in claim 5, wherein a solid phase and a liquid phase are present during the pulling of the single crystal, and wherein an interface between the solid phase and liquid phase, at which crystal growth occurs by deposition from the liquid phase melt, has a concave form.

7. The method as recited in claim 5, wherein the solid materials having abrasive action are selected from the group consisting of cerium oxides, aluminum oxides, silicon oxides, zirconium oxides, silicon carbide, boron nitride and diamond.

8. The method as recited in claim 7, wherein the solid materials having abrasive action have a size in a range of 0.1-1.0 μm.

9. The method as recited in claim 5, wherein a solid phase and a liquid phase are present during the pulling of the single crystal, and wherein an interface between the solid phase and liquid phase, at which crystal growth occurs by deposition from the liquid phase melt, has a trapezoidal form.

10. The method as recited in claim 6, wherein the interface has a trapezoidal form.

11. The method as recited in claim 5, wherein a solid phase and a liquid phase are present during pulling of the single crystal, and wherein an interface between the solid and liquid phase, at which crystal growth occurs by deposition from the liquid phase melt, has a higher gradient in an edge region of the single crystal than in the center region of the single crystal, such that a fluctuation of a radial concentration of dopant incorporated at the interface is high in the edge region and there are small radial distances between concentration maxima.

12. The method as recited in claim 6, wherein a solid phase and a liquid phase are present during pulling of the single crystal, and wherein an interface between the solid and liquid phase, at which crystal growth occurs by deposition from the liquid phase melt, has a higher gradient in an edge region of the single crystal than in the center region of the single crystal, such that a fluctuation of a radial concentration of dopant incorporated at the interface is high in the edge region and there are small radial distances between concentration maxima.

13. The method as recited in claim 10, wherein a solid phase and a liquid phase are present during pulling of the single crystal, and wherein an interface between the solid and liquid phase, at which crystal growth occurs by deposition from the liquid phase melt, has a higher gradient in an edge region of the single crystal than in the center region of the single crystal, such that a fluctuation of a radial concentration of dopant incorporated at the interface is high in the edge region and there are small radial distances between concentration maxima.

14. The method as recited in claim 13, the interface between the solid and liquid phase is substantially flat at a center of the single crystal such that the fluctuation of radial concentration of the dopant in the center of the single crystal is low and there are wide radial distances between concentration maxima.

15. A semiconductor wafer having an edge region and a center region, the edge region having a high fluctuation of radial concentration of dopant, wherein the semiconductor wafer is formed by:
pulling a single crystal including semiconductor material, so as to form a single crystal having an edge region having high fluctuation of dopant concentration at spatially high-frequency and a center region having low fluctuation of dopant concentration at spatially low-frequency;
slicing a semiconductor wafer from the single crystal;
supplying a polishing agent that is free of solid materials having abrasive action in a gap between the semiconductor wafer and a polishing pad containing fixedly bonded solid materials with abrasive action, the polishing agent having a pH value in a range of 9.5 to 12.5; and
polishing the semiconductor wafer with the polishing pad and polishing agent.

16. The semiconductor wafer as recited in claim 15, wherein the center region has a low fluctuation of radial concentration of dopant.
